(19) United States
(12) Patent Application Publication
(10) Pub. No.: US 2026/0188388 A1
(43) Pub. Date: Jul. 2, 2026

(54) MEMORY DEVICE INCLUDING A FILTERING CIRCUIT AND MEMORY SYSTEM INCLUDING THE MEMORY DEVICE

(71) Applicant: SK hynix Inc., Icheon-si Gyeonggi-do (KR)

(72) Inventors: Jong Soon WON, Icheon-si Gyeonggi-do (KR); Hae Rang CHOI, Icheon-si Gyeonggi-do (KR)

(73) Assignee: SK hynix Inc., Icheon-si Gyeonggi-do (KR)

(21) Appl. No.: 19/548,787

(22) Filed: Feb. 24, 2026

Related U.S. Application Data
(63) Continuation-in-part of application No. 18/349,654, filed on Jul. 10, 2023, now Pat. No. 12,586,613.

(30) Foreign Application Priority Data
Jan. 30, 2023 (KR) 10-2023-0012192

(51) Int. Cl. G11C 16/10; G11C 16/26; G11C 16/32

(52) U.S. Cl. CPC G11C 16/102; G11C 16/26; G11C 16/32

(57) ABSTRACT

A high bandwidth memory (HBM) device includes a plurality of core dies each comprising a plurality of memory circuits, and a logic die stacked with the plurality of core dies. The logic die includes a filtering circuit configured to perform a filtering operation on data, and an input/output interface configured to perform a data input/output operation with an external device. The filtering circuit is configured to directly receive write data from the external device through the input/output interface, perform the filtering operation on the write data before the write data is stored in the plurality of memory circuits, and transmit filtered write data to at least one of the plurality of memory circuits.

### CROSS-REFERENCE TO RELATED APPLICATIONS

The present application is a continuation-in-part of U.S. patent application Ser. No. 18/349,654, filed on Jul. 10, 2023, which claims priority under 35 U.S.C. § 119(a) to Korean Patent Application No. 10-2023-0012192, filed in the Korean Intellectual Property Office on Jan. 30, 2023, the entire contents of which applications are incorporated herein by reference.

### BACKGROUND

### 1. Technical Field

Embodiments of the present disclosure generally relate to a memory device and memory system including the memory device, and more particularly, to a memory device including a filtering circuit and memory systems including the memory device and filtering circuit.

### 2. Related Art

Recently, with the development of internet technology, large-scale data are being generated and distributed. It is becoming a competitive edge for companies to accumulate huge amounts of data, extract meaningful information as quickly as possible, and provide extracted information to users who requested the information. For this reason, in recent years, research has been conducted on large-scale data distribution processing and work distribution parallel processing technology by constructing a large-scale cluster at low cost. In addition, as people's online connections such as multimedia, Internet of Things (IoT), and cloud computing diversify, data traffic on the internet connection network steadily increases, and computing power to process data increases. As computing power increases, it became possible to process large amounts of data, and as a result, demand for memory devices increases. However, due to the bottleneck phenomenon caused by the increase in data traffic, the performance of the entire computing system is degraded.

Typically, filtering operations on data are performed in a host device, such as a central processing unit (CPU). In this case, in order to filter the data stored in an external storage device and store the data in a memory device, first, the data is loaded from the external storage device into the memory device. Next, the data loaded into the memory device is read into a cache memory of the central processing unit. Next, the processing unit of the central processing unit performs filtering on the data read into the cache memory, and writes the filtered data in the cache memory of the central processing unit. Next, the data written in the cache memory is written in the memory device. In this manner, the data from the external storage device is filtered through the memory device and the central processing unit, and the filtered data is moved from the central processing unit to the memory device again. In general, the time required for the filtering operation in the central processing unit is shorter than a data transfer time, and thus, the bottleneck phenomenon may occur in the memory device. Moreover, the larger the size of the data, the higher the latency and power consumption.

### SUMMARY

According to an embodiment of the present disclosure, a high bandwidth memory (HBM) device may comprise a plurality of core dies each comprising a plurality of memory circuits, and a logic die stacked with the plurality of core dies. The logic die may comprise a filtering circuit configured to perform a filtering operation on data, and an input/output interface configured to perform a data input/output operation with an external device. The filtering circuit may be configured to directly receive write data from the external device through the input/output interface, perform the filtering operation on the write data before the write data is stored in the plurality of memory circuits, and transmit filtered write data to at least one of the plurality of memory circuits.

According to an embodiment of the present disclosure, a solid state drive (SSD) device may comprise a non-volatile memory cell array comprising a plurality of planes, a peripheral circuit region disposed adjacent to the non-volatile memory cell array and comprising a page buffer and a filtering circuit, and a controller configured to control the non-volatile memory cell array. The filtering circuit may be configured to receive data read from the memory cell array through the page buffer, perform a filtering operation on the data before the data is transmitted to the controller, and transmit filtered data to the controller.

According to an embodiment of the present disclosure, a high bandwidth flash (HBF) device may comprise a plurality of memory dies each comprising a non-volatile memory cell array, and a logic die stacked with the plurality of memory dies. The logic die may comprise a controller configured to control the plurality of memory dies, a filtering circuit configured to perform a filtering operation on data, and an interface configured to perform a data input/output operation with an external device. The filtering circuit may be configured to receive data read from the plurality of memory dies, perform the filtering operation on the data before the data is processed by the controller, and transmit filtered data to the controller.

### BRIEF DESCRIPTION OF THE DRAWINGS

FIG. 1 is a block diagram illustrating a memory device according to an embodiment of the present disclosure.

FIG. 2 is a block diagram illustrating a filtering circuit included in a memory device according to an embodiment of the present disclosure.

FIG. 3 is a diagram illustrating an example of a data filtering operation of a filtering logic circuit included in the filtering circuit of FIG. 2.

FIG. 4 is a diagram illustrating another example of the data filtering operation of the filtering logic circuit included in the filtering circuit of FIG. 2.

FIG. 5 is a diagram illustrating further another example of the data filtering operation of the filtering logic circuit included in the filtering circuit of FIG. 2.

FIG. 6 is a diagram illustrating further another example of the data filtering operation of the filtering logic circuit included in the filtering circuit of FIG. 2.

FIG. 7 is a diagram illustrating further another example of the data filtering operation of the filtering logic circuit included in the filtering circuit of FIG. 2.

FIG. 8 is a block diagram illustrating a memory system according to an embodiment of the present disclosure.

FIGS. 9 and 10 are block diagrams illustrating a filtering process for write data in the memory system of FIG. 8.

FIGS. 11 and 12 are block diagrams illustrating a filtering process for read data in the memory system of FIG. 8.

FIG. 13 is a block diagram illustrating a memory device according to another embodiment of the present disclosure.

FIG. 14 is a block diagram illustrating a memory system according to still further another embodiment of the present disclosure.

FIG. 15 is illustrates a high bandwidth memory (HBM) device including a filtering circuit according to an embodiment of the present disclosure.

FIG. 16 is illustrates a solid states drive (SSD) device including a filtering circuit according to an embodiment of the present disclosure.

FIG. 17 is illustrates a high bandwidth flash (HBF) device including a filtering circuit according to an embodiment of the present disclosure.

### DETAILED DESCRIPTION

In the description of the embodiments of the present disclosure, descriptions such as “first” and “second” are for distinguishing elements, and are not used to limit the members themselves or to mean a specific order. The description that one component is “connected” or “coupled” to another component may be electrically or mechanically directly connected or connected to another component. Alternatively, other separate components may be interposed in the middle to form a connection relationship. The term “predetermined” means that the value of a parameter is predetermined when using that parameter in a process or algorithm. The value of the parameter may be set when a process or algorithm starts or may be set during a period during which a process or algorithm is performed, depending on embodiments.

“Logic high level” and “logic low level” are used to describe logic levels of signals. A signal having a “logic high level” is distinguished from a signal having a “logic low level”. For example, when a signal having a first voltage corresponds to a “logic high level”, a signal having a second voltage may correspond to a “logic low level”. According to an embodiment, the “logic high level” may be set to a higher voltage than the “logic low level”. Meanwhile, the logic levels of the signals may be set to other logic levels or opposite logic levels according to embodiments. For example, a signal having a logic high level may be set to have a logic low level according to embodiments, and a signal having a logic low level may be set to have a logic high level according to embodiments.

Various embodiments of the present disclosure will be described hereinafter in more detail with reference to the accompanying drawings. Various embodiments described below take DRAM as an example as a memory device, but it is obvious that it is not limited thereto. For example, the same can be applied to static random access memory (SRAM), Synchronous DRAM (SDRAM), double data rate synchronous DRAM (DDR SDRAM, DDR2 SDRAM, DDR3 SDRAM, etc.), graphics double data rate synchronous DRAM (GDDR, GDDR2, GDDR3, etc.), quad data rate DRAM (QDR DRAM), RAMBUS XDR DRAM (XDR DRAM), fast page mode DRAM (FPM DRAM), video DRAM (VDRAM), extended data output DRAM (EDO DRAM), burst EDO DRAM (BEDO DRAM), multi-bank DRAM (MDRAM), synchronous graphic RAM (SGRAM), and/or other types of DRAM.

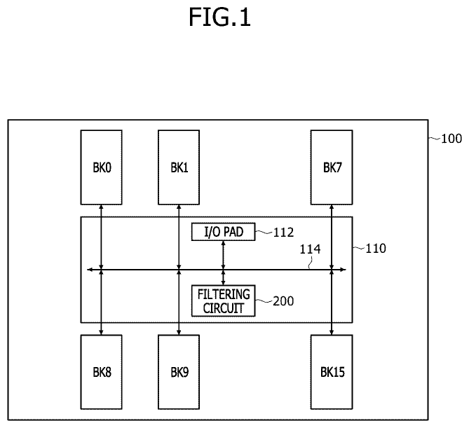

FIG. 1 is a block diagram illustrating a memory device 100 according to an embodiment of the present disclosure. Referring to FIG. 1, the memory device 100 may include a plurality of memory circuits BK1-BK15, an input/output pad (I/O pad) 112, a global input/output (GIO) line 114, and a filtering circuit 200. In an embodiment, the plurality of memory circuits BK0-BK15 may be composed of DRAM devices. The plurality of memory circuits BK0-BK15 may be composed of memory banks. In this embodiment, the memory device 100 includes sixteen memory circuits BK0-BK15, but the memory device 100 may include more or less than sixteen memory circuits. The plurality of memory circuits BK0-BK15 may perform a data read operation and a data write operation upon request from a host device, for example, a central processing unit (CPU). The plurality of memory circuits BK0-BK15 may exchange data with the input/output pad 112 and the filtering circuit 200 through the GIO line 114. Although not illustrated in FIG. 1, the memory device 100 may be a processing-in-memory (PIM) device. In this case, the memory device 100 may include a plurality of processing elements coupled to the plurality of memory circuits BK0-BK15. The plurality of processing elements may receive data from the memory circuits BK0-BK15 and perform various types of arithmetic operations.

The input/output pad 112 may perform a data input/output operation with the outside of the memory device 100. That is, the memory device 100 may receive data from an external device, for example, a host device or an external storage device, through the input/output pad 112. In addition, the memory device 100 may output data to the external device through the input/output pad 112. The input/output pad 112 may be disposed within a peripheral circuit 110 of the memory device 100. The input/output pad 112 may be coupled to the GIO line 114. When data is transmitted from the external device, the input/output pad 112 may transmit the data to the plurality of memory circuits BK0-BK15 or the filtering circuit 200 through the GIO line 114. The input/output pad 112 may receive data from the plurality of memory circuits BK0-BK15 or the filtering circuit 200 through the GIO line 114, and output the data to the external device.

The GIO line 114 may provide data transmission paths among the plurality of memory circuits BK0-BK15, the input/output pad 112, and the filtering circuit 200. That is, the GIO line 114 may provide paths through which data can be transmitted among the plurality of memory circuits BK0-BK15 and the input/output pad 112. The GIO line 114 may provide paths through which data can be transmitted among the plurality of memory circuits BK0-BK15 and the filtering circuit 200. In addition, the GIO line 114 may provide a path through which data can be transmitted between the input/output pad 112 and the filtering circuit 200.

The filtering circuit 200 may perform a filtering operation on input data, and transmit filtered data to the plurality of memory circuits BK0-BK15 or transmit the filtered data to an external device. The filtering operation performed by the filtering circuit 200 may include a conditional arithmetic operation on the input data. That is, the filtering circuit 200 may filter and output only data that meets a specific condition from the input data. In an example, the data input to the filtering circuit 200 may be numeric data, for example, data in a fixed-point format, data in a floating-point format, integer data, decimal data, and the like. However, this is just one example, and data input to the filtering circuit 200 may be various types of data other than numeric data.

The filtering circuit 200 may directly receive write data from an external storage device through the input/output pad 112 and the GIO line 114. Thus, the write data is transmitted to the filtering circuit 200 without going through memory circuits. In this case, the filtering circuit 200 may perform a filtering operation on the write data and transmit filtered write data to the plurality of memory circuits BK0-BK15 through the GIO line 114. The filtering circuit 200 may directly receive read data from the plurality of memory circuits BK0-BK15 through the GIO line 114. In this case, the filtering circuit 200 may perform a filtering operation on the read data and transmit filtered read data to an external device, such as a host device, through the GIO line 114 and the input/output pad 112.

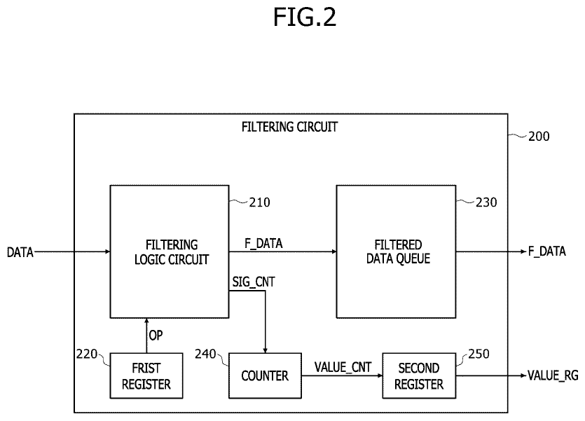

FIG. 2 is a block diagram illustrating the filtering circuit 200 included in the memory device 100 in FIG. 1. Referring to FIG. 2, the filtering circuit 200 may include a filtering logic circuit 210, a first register 220, a filtered data queue 230, a counter 240, and a second register 250.

The filtering logic circuit 210 may receive data transmitted to the filtering circuit 200. The filtering logic circuit 210 may perform a data filtering operation on the input data, and generate filtered data F_DATA and a counting signal SIG_CNT. The filtering logic circuit 210 may receive an operand OP required to perform the filtering operation from the first register 220. In an embodiment, the operand OP provided to the filtering logic circuit 210 may be a conditional operand. The filtering logic circuit 210 may transmit the filtered data F_DATA to the filtered data queue 230. The filtering logic circuit 210 may transmit the counting signal SIG_CNT to the counter 240. The filtering logic circuit 210 may output the counting signal SIG_CNT together whenever outputting the filtered data F_DATA. In an embodiment, the filtering logic circuit 210 may include a logic circuit necessary for the filtering operation, such as a logarithmic comparator or an arithmetic operator. In another embodiment, the filtering logic circuit 210 may include a logic circuit necessary for an encryption operation, such as an encryption circuit. The filtering logic circuit 210 may be configured as a programmable logic circuit.

The first register 220 may store the operand OP provided to the filtering logic circuit 210. The first register 220 may receive and store the operand OP required for a data filtering operation, before the data filtering operation is performed in the filtering logic circuit 210. For example, when the data filtering operation is an operation of comparing data with a specific value, the first register 220 may receive and store the specific value in advance. In addition, the first register 220 may provide the specific value to the filtering logic circuit 210 so that the filtering logic circuit 210 may perform an operation of comparing data with the specific value. The first register 220 may provide a plurality of operands OPs to the filtering logic circuit 210.

The filtered data queue 230 may store the filtered data F_DATA transmitted from the filtering logic circuit 210. Although not illustrated in FIG. 2, the filtered data queue 230 may output the filtered data F_DATA in response to an output control signal. In an embodiment, when the number of pieces of the stored filtered data F_DATA exceeds a certain number, the filtered data queue 230 may output the stored filtered data F_DATA. In an embodiment, the filtered data queue 230 may output the stored filtered data F_DATA in a first-in-first-out (FIFO) method.

The counter 240 may count the number of the filtered data F_DATA that is filtered by the filtering logic circuit 210. The counter 240 may perform a counting operation in response to the counting signal SIG_CNT transmitted from the filtering logic circuit 210 to generate a counting value VALUE_CNT. Because the filtering logic circuit 210 outputs the counting signal SIG_CNT whenever outputting the filtered data F_DATA, the counting value VALUE_CNT output from the counter 240 may correspond to the number of pieces of the filtered data F_DATA filtered by the filtering logic circuit 210.

The second register 250 may receive and store the counting value VALUE_CNT from the counter 240. Although not illustrated in FIG. 2, the second register 250 may receive the output control signal. The second register 250 may output the stored counting value VALUE_CNT as a register value VALUE_RG in response to the output control signal. In an embodiment, the register value VALUE_RG output from the second register 250 may be transmitted to a host device as meta data.

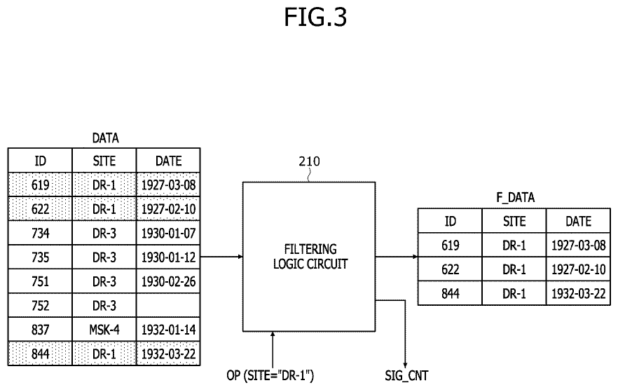

FIG. 3 is a diagram illustrating an example of a data filtering operation of the filtering logic circuit 210 included in the filtering circuit 200 of FIG. 2. As illustrated in FIG. 3, a case in which data DATA having eight entries for each of items of identification ID, observation site SITE, and observation date DATE is input to the filtering logic circuit 210 will be taken as an example.

Referring to FIG. 3, the filtering logic circuit 210 may receive the operand OP having an observation site SITE that has a value of “DR-1” from the first register (220 in FIG. 2). The filtering logic circuit 210 may filter out the remaining entries except for the entry satisfying a condition specified by the operand OP, that is, the entries having an observation site SITE that is “DR-1”, for the entries of the data DATA. As illustrated in FIG. 3, while all observation sites SITEs of entries having identification ID of “619,” “622,” and “844” are “DR-1”, the observation sites SITEs of the remaining entries all have values different from “DR-1”. Accordingly, the filtering logic circuit 210 may output the entries having an observation site SITE is “DR-1”, that is, entries with identifications IDs of “619,” “622,” and “844” as the filtered data F_DATA, and not output the remaining entries. The filtering logic circuit 210 may output the filtered data F_DATA, which is a result of the data filtering operation, together with the counting signal SIG_CNT and transmit the counting signal SIG_CNT to the counter (240 in FIG. 2).

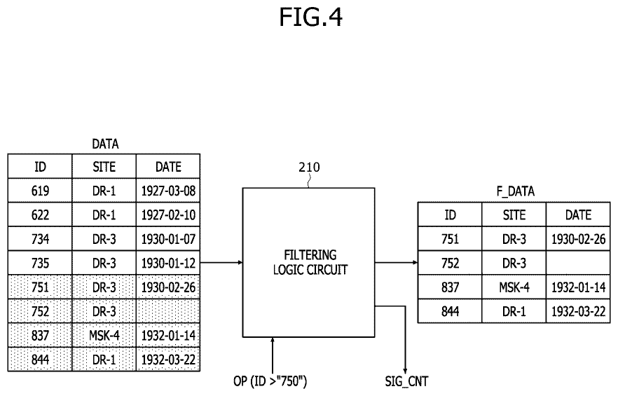

FIG. 4 is a diagram illustrating another example of the data filtering operation of the filtering logic circuit 210 included in the filtering circuit 200 of FIG. 2. In this example as well, as described with reference to FIG. 3, a case in which data DATA having eight entries for each of items of identification ID, observation site SITE, and observation date DATE is input to the filtering logic circuit 210 will be taken as an example.

Referring to FIG. 4, the filtering logic circuit 210 may receive an operand OP with a condition that the identification ID is greater than “750” from the first register (220 in FIG. 2). The filtering logic circuit 210 may filter out the remaining entries except for the entries that satisfy the condition specified by the operand OP, that is, entries having identification ID that is greater than “750”, for the entries of the data DATA. As exemplified in FIG. 4, while identifications IDs of the entries having identification ID that is “751,” “752,” “837,” and “844” are all greater than “750”, the identifications IDs of the remaining entries are all smaller than “750”. Accordingly, the filtering logic circuit 210 may output the entries having the identification ID greater than “750”, that is, the entries having the identification ID of “751,” “752,” “837,” and “844” as the filtered data F_DATA, and not output the remaining entries. The filtering logic circuit 210 may output the filtered data F_DATA, which is a result of the data filtering operation, together with the counting signal SIG_CNT, and transmit the counting signal SIG_CNT to the counter (240 in FIG. 2).

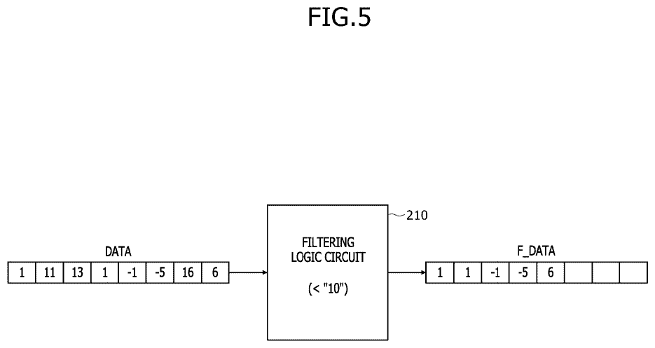

FIG. 5 is a diagram illustrating further another example of the data filtering operation of the filtering logic circuit 210 included in the filtering circuit 200 of FIG. 2. Referring to FIG. 5, a case where data DATA in which values of “1,” “11,” “13,” “1,” “−1,” “−5,” “16,” and “6” are sequentially arranged is input to the filtering logic circuit 210, and a conditional operand OP having a condition of less than “10” is set in the filtering logic circuit 210 will be taken as an example. In this case, the filtering logic circuit 210 may output only values less than “10”, that is, values of “1,” “1,” “−1,” “−5,” and “6” as the filtered data F_DATA among the values of “1,” “11,” “13,” “1,” “−1,” “−5,” “16,” and “6” included in the data DATA. In this example, the size of the filtered data F_DATA output from the filtering logic circuit 210 may be smaller than the size of the data DATA input to the filtering logic circuit 210.

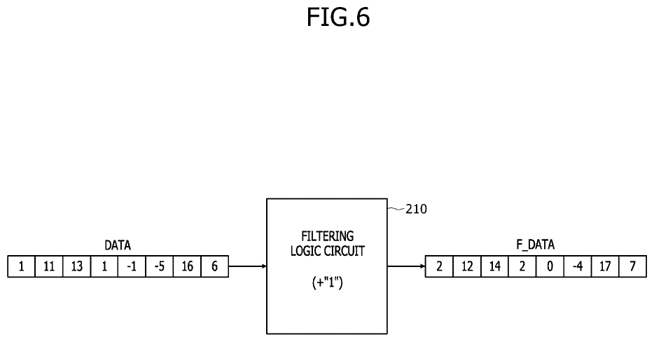

FIG. 6 is a diagram illustrating further another example of the data filtering operation of the filtering logic circuit 210 included in the filtering circuit 200 of FIG. 2. Referring to FIG. 6, a case where the data DATA in which values of “1,” “11,” “13,” “1,” “−1,” “−5,” “16,” and “6” are sequentially arranged is input to the filtering logic circuit 210 and a conditional operand OP having a condition of adding “1”, that is, +“1” is set in the filtering logic circuit 210 will be taken as an example. In this case, the filtering logic circuit 210 may add “1” to the values of “1,” “11,” “13,” “1,” “−1,” “−5,” “16,” and “6” included in the data DATA to output the filtered data F_DATA having values of “2,” “12,” “14,” “2,” “0,” “−4,” “17,” and “7”. In this example, the size of the data DATA input to the filtering logic circuit 210 and the size of the filtered data F_DATA output from the filtering logic circuit 210 may be the same.

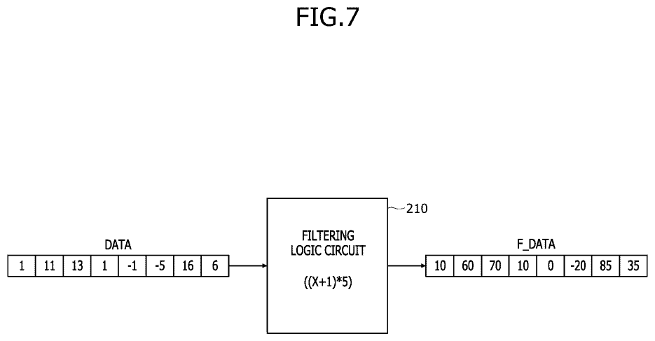

FIG. 7 is a diagram illustrating further another example of the data filtering operation of the filtering logic circuit 210 included in the filtering circuit 200 of FIG. 2. Referring to FIG. 7, a case in which data DATA in which values of “1,” “11,” “13,” “1,” “−1,” “−5,” “16,” and “6” are sequentially arranged is input to the filtering logic circuit 210 and a conditional operand OP having a condition of multiplying by “5” after adding “1”, that is, “(X+1)*5” is set in the filtering logic circuit 210 will be taken as an example. Here, “X” may represent the value of input data DATA. In this case, the filtering logic circuit 210 may add “1” to each of the values of “1,” “11,” “13,” “1,” “−1,” “−5,” “16,” and “6” included in the data DATA and multiply by “5” to output the filtered data F_DATA having values of “10,” “60,” “70,” “10,” “0,” “−20,” “85,” and “35”. Even in this example, the size of the data DATA input to the filtering logic circuit 210 and the size of the filtered data F_DATA output from the filtering logic circuit 210 may be the same.

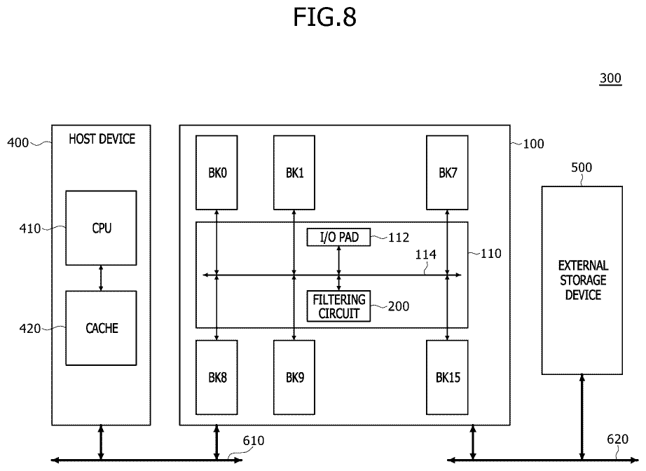

FIG. 8 is a block diagram illustrating a memory system 300 according to an embodiment of the present disclosure. Referring to FIG. 8, the memory system 300 may include a memory device 100, a host device 400, and an external storage device 500. A configuration of the memory device 100 may be the same as that described with reference to FIGS. 1 to 8. That is, the memory device 100 may include a plurality of memory circuits BK0-BK15 and a filtering circuit 200.

The memory device 100 and the host device 400 may exchange data with each other through a first data bus 610. The memory device 100 and the external storage device 500 may exchange data with each other through a second data bus 620. The host device 400 may include a central processing unit (CPU) 410 and a cache memory 420. The CPU 410 may transmit data to the cache memory 420 or receive data from the cache memory 420. The cache memory 420 may communicate with the first data bus 610. Accordingly, the cache memory 420 may transmit data to the memory device 100 or receive data from the memory device 100 through the first data bus 610. In an embodiment, the external storage device 500 may be a hard disk drive (HDD) or a solid-state drive (SSD). In another embodiment, the external storage device 500 may be a network storage device. The external storage device 500 may transmit data to the memory device 100 or receive data from the memory device 100 through the second data bus 620. In the memory system 300 according to the present embodiment, the memory device 100 may perform a read operation, a write operation, and an arithmetic operation according to a request from the host device 400. In addition, the external storage device 500 may provide stored data to the memory device 100 or receive and store data from the memory device 100.

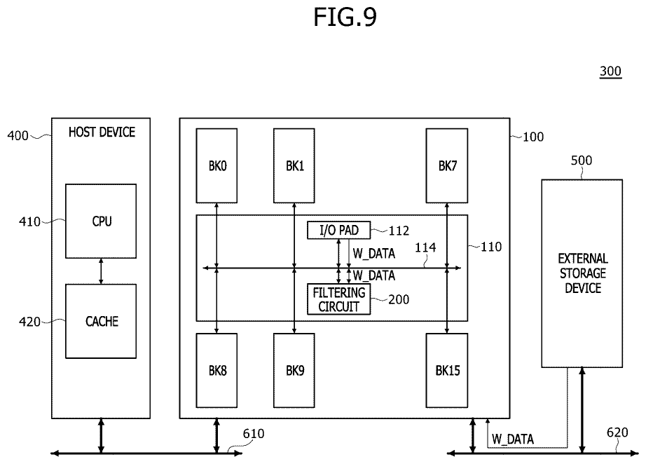

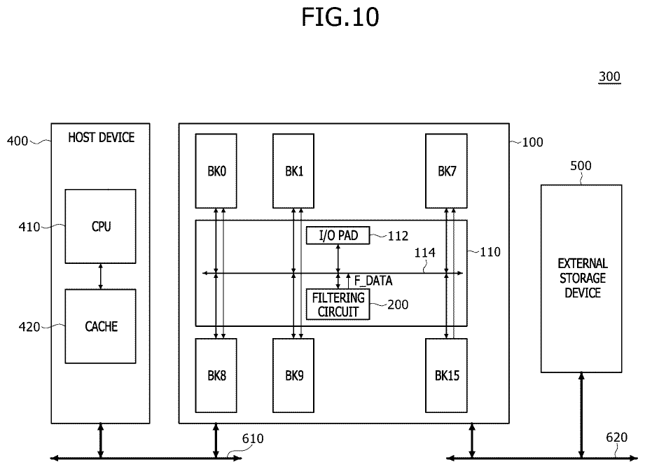

FIGS. 9 and 10 are block diagrams illustrating a filtering process for write data in the memory system 300 of FIG. 8. In FIGS. 9 and 10, the same reference numerals as those in FIG. 8 denote the same components, and duplicate descriptions will be omitted.

First, as illustrated in FIG. 9, the external storage device 500 may transmit write data W_DATA to the memory device 100 through the second data bus 620 at the request of the host device 400. An input/output pad 112 of the memory device 100 may transmit the write data W_DATA transmitted from the external storage device 500 to the filtering circuit 200 through a GIO line 114. Next, as illustrated in FIG. 10, the filtering circuit 200 may perform a filtering operation on the write data W_DATA to generate filtered data F_DATA. Next, the filtering circuit 200 may transmit the filtered data F_DATA to the first to sixteenth memory circuits BK0-BK15 through the GIO line 114. As such, when a filtering operation on the write data is performed in the memory system 300 according to the present embodiment, the write data W_DATA from the external storage device 500 may be directly filtered and written within the memory device 100 without passing through the host device 400.

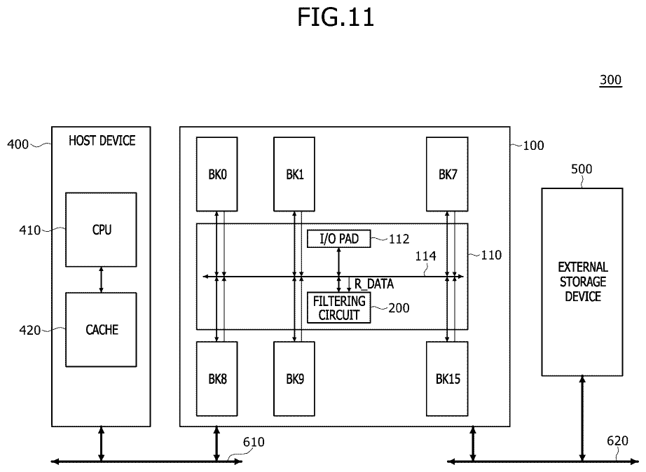

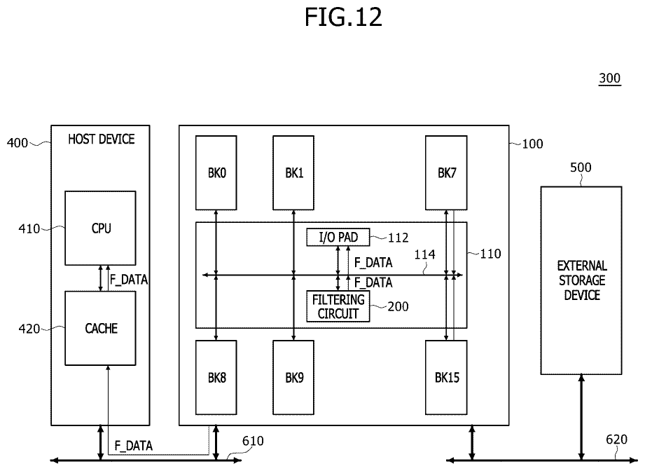

FIGS. 11 and 12 are block diagrams illustrating a filtering process for read data in the memory system 300 of FIG. 8. In FIGS. 11 and 12, the same reference numerals as those in FIG. 8 denote the same components, and duplicate descriptions will be omitted.

First, as illustrated in FIG. 11, at the request of the host device 400, the first to sixteenth memory circuits BK0-BK15 of the memory device 100 may transmit read data R_DATA to the filtering circuit 200 of the memory device 100 through the GIO line 114. Next, as illustrated in FIG. 12, the filtering circuit 200 may perform a filtering operation on the read data (R_DATA in FIG. 11) to generate filtered data F_DATA. Next, the filtering circuit 200 may transmit the filtered data F_DATA to the first data bus 610 through the GIO line 114 and the input/output pad 112. The filtered data F_DATA transmitted from the memory device 100 to the first data bus 610 may be transmitted to the cache memory 420 of the host device 400. The filtered data F_DATA transmitted to the cache memory 420 may be transmitted to the CPU 410.

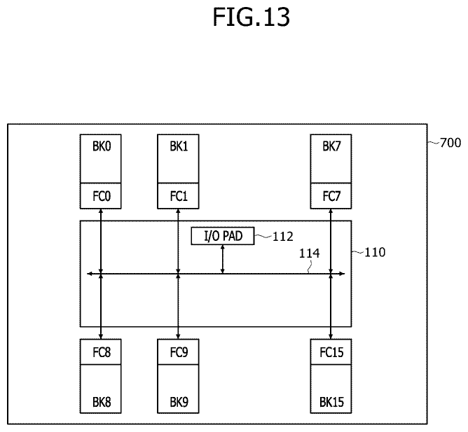

FIG. 13 is a block diagram illustrating a memory device 700 according to another embodiment of the present disclosure. In FIG. 13, the same reference numerals as those in FIG. 1 denote the same components, and duplicate descriptions will be omitted below. Referring to FIG. 13, the memory device 700 may include a plurality of, for example, first to sixteenth memory circuits BK0-BK15, and a plurality of, for example, first to sixteenth filtering circuits FC0-FC15. Each of the first to sixteenth filtering circuits FC0-FC15 may be configured identically to the filtering circuit 200 described with reference to FIGS. 1 to 7. In an example, the first to sixteenth filtering circuits FC0-FC15 may perform the same filtering operation. In another example, the first to sixteenth filtering circuits FC0-FC15 may perform different filtering operations. The first to sixteenth filtering circuits FC0-FC15 may be disposed to correspond to the first to sixteenth memory circuits BK0-BK15, respectively. That is, one of the first to sixteenth filtering circuits FC0-FC15 and a corresponding one of the first to sixteenth memory circuits BK0-BK15 may constitute one memory-filtering circuit pair. As illustrated in FIG. 13, the first filtering circuit FC0 and the first memory circuit BK0 may constitute a first memory-filtering circuit pair. The second filtering circuit FC1 and the second memory circuit BK1 may constitute a second memory-filtering circuit pair. Similarly, the sixteenth filtering circuit FC15 and the sixteenth memory circuit BK15 may constitute a sixteenth memory-filtering circuit pair.

The first to sixteenth filtering circuits FC0-FC15 may receive write data transmitted from an external device of the memory device 700, for example, an external storage device to an input/output pad 112 through a GIO line 114. In this case, the first to sixteenth filtering circuits FC0-FC15 may perform a data filtering operation on the write data to generate filtered write data. The first to sixteenth filtering circuits FC0-FC15 may transmit the filtered write data to the first to sixteenth memory circuits BK0-BK15.

The first to sixteenth filtering circuits FC0-FC15 may receive read data from the first to sixteenth memory circuits BK0-BK15. In this case, the first to sixteenth filtering circuits FC0-FC15 may perform a data filtering operation on the read data to generate filtered read data. The first to sixteenth filtering circuits FC0-FC15 may transmit the filtered read data to the external device of the memory device 700, for example, a host device through the GIO line 114 and the input/output pad 112.

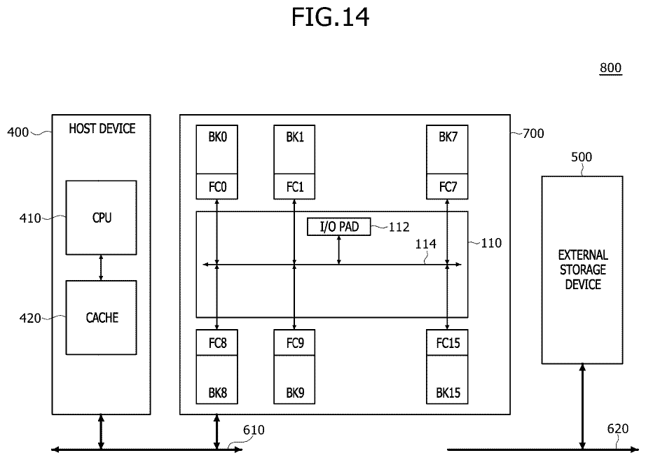

FIG. 14 is a block diagram illustrating a memory system 800 according to another embodiment of the present disclosure. Referring to FIG. 14, the memory system 800 may include a memory device 700, a host device 400, and an external storage device 500. A configuration of the memory device 700 may be the same as that described with reference to FIG. 13. That is, the memory device 700 may include a plurality of memory circuits BK0-BK15 and a plurality of filtering circuits FC0-FC15.

Configurations of the host device 400 and the external storage device 500 may be the same as those described with reference to FIG. 8. That is, the memory device 100 and the host device 400 may exchange data with each other through a first data bus 610. The memory device 100 and the external storage device 500 may exchange data with each other through a second data bus 620. The host device 400 may include a central processing unit (CPU) 410 and a cache memory 420. The external storage device 500 may transmit data to the memory device 100 or receive data from the memory device 100 through the second data bus 620. In the memory system 800 according to the present embodiment, the memory device 700 may perform a read operation, a write operation, and an arithmetic operation according to a request from the host device 400. In addition, the external storage device 500 may provide stored data to the memory device 700 or receive and store data from the memory device 700.

In order to filter write data from the external storage device 500 to write the write data in the memory circuits BK0-BK15 of the memory device 700, first, the external storage device 500 may transmit the write data to the input/output pad 112 of the memory device 700 through the second data bus 620. The write data transmitted to the input/output pad 112 may be transmitted to first to sixteenth filtering circuits FC0-FC15 through the input/output pad 112 and the GIO line 114 of the memory device 700. In this case, the write data may be distributed and transmitted to the first to sixteenth filtering circuits FC0-FC15 or may be transmitted in common. The first to sixteenth filtering circuits FC0-FC15 may perform a data filtering operation on the received write data to generate filtered write data. The first to sixteenth filtering circuits FC0-FC15 may perform the same type of data filtering operation on the received write data, or may perform different types of data filtering operations on the received write data. The first to sixteenth filtering circuits FC0-FC15 may transmit the filtered write data to first to sixteenth memory circuits BK0-BK15.

In order to filter and read the read data stored in the first to sixteenth memory circuits BK0-BK15 of the memory device 700, first, the first to sixteenth memory circuits BK0-BK15 may transmit the read data to the first to sixteenth filtering circuits FC0-FC15. The first to sixteenth filtering circuits FC0-FC15 may perform a data filtering operation on the received read data to generate filtered read data. The first to sixteenth filtering circuits FC0-FC15 may transmit the filtered read data to the first data bus 610 through the GIO line 114 and the input/output pad 112. In addition, the filtered read data may be transmitted to the host device 400 through the first data bus 610.

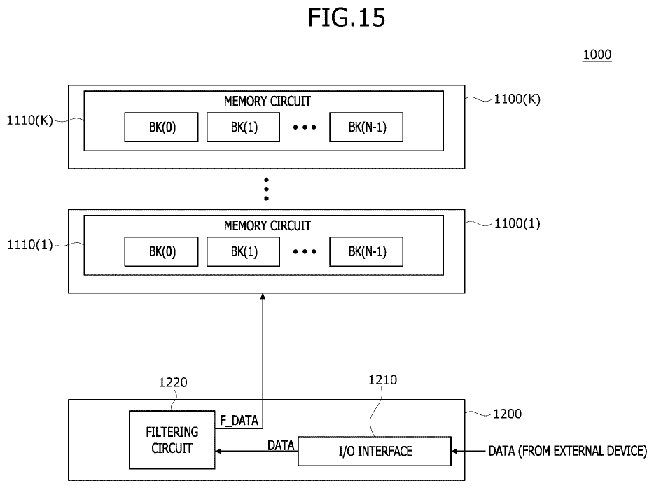

FIG. 15 is illustrates a high bandwidth memory (HBM) device including a filtering circuit according to an embodiment of the present disclosure.

Referring to FIG. 15, the HBM device 1000 may comprise a plurality of core dies, for example first to K-th core dies 1100(1) to 1100(K), and a logic die 1200 stacked with the first to K-th core dies 1100(1) to 1100(K). Here, K is a natural number equal to or greater than two. The first to K-th core dies 1100(1) to 1100(K) may respectively comprise first to K-th memory circuits 1110(1) to 1110(K). For example, the first core die 1100(1) may comprise the first memory circuit 1110(1), and the K-th core die 1100(K) may comprise the K-th memory circuit 1110(K).

Each of the first to K-th memory circuits 1110(1) to 1110(K) may comprise a plurality of memory banks, for example first to N-th memory banks BK(0) to BK(N−1). The first to N-th memory banks BK(0) to BK(N−1) may be implemented as storage units independently activated to enable parallel data access and increased bandwidth. In one embodiment, the first to K-th memory circuits 1110(1) to 1110(K) may be formed using the same fabrication process. The first to K-th core dies 1100(1) to 1100(K) may have a stacked structure in which multiple layers are formed along a stacking direction. Although not illustrated in the drawings, each of the first to K-th core dies 1100(1)-1100(K) may include vertical interconnects such as through-silicon vias (TSVs). The first to K-th core dies 1100(1)-1100(K) may be electrically connected to one another through hybrid bonding, micro-bumps, Cu—Cu direct bonding, or the like.

The logic die 1200 may be formed as a die separate from the first to K-th core dies 1100(1) to 1100(K) and may be disposed below or above the first to K-th core dies 1100(1) to 1100(K) in a stacked configuration. The logic die 1200 may include vertical interconnects such as TSVs. The TSVs may provide vertical electrical paths for transmitting signals and data in the stacking direction. The TSVs of the logic die 1200 and the TSVs of the first core die 1100(1) may be electrically connected to each other through hybrid bonding, micro-bumps, Cu-Cu direct bonding, or the like.

In one embodiment, the logic die 1200 may comprise a memory controller block supporting HBM3 or a higher standard. The memory controller block may comprise a plurality of memory channels and a plurality of pseudo-channel control circuits corresponding to each memory channel. Each pseudo channel may have an independent command bus, address bus, and data bus, and may be configured to perform parallel control of a plurality of bank groups.

The logic die 1200 may further comprise a command decoder, an address decoder, bank control logic, a bank group scheduler, and a data scheduling circuit. The command decoder may interpret commands received from an external device and distinguish among read commands, write commands, activate commands, precharge commands, and other memory commands. The address decoder may decode received address information to designate a specific core die among the first to K-th core dies 1100(1) to 1100(K) and a specific memory bank BK(0) to BK(N−1) within the designated core die.

The logic die 1200 may further comprise a global interconnection structure. The global interconnection structure may comprise data lines, address lines, and control lines, and may be connected to the first to K-th core dies 1100(1) to 1100(K) through the TSVs. In one embodiment, the global interconnection structure may be implemented as a TSV crossbar switch structure to support dynamic routing between a plurality of pseudo channels and a plurality of core dies.

The logic die 1200 may further comprise a refresh controller, a power management circuit, a clock management circuit, and an error correction code (ECC) block. The refresh controller may be configured to perform fine granularity refresh operations for each memory bank. The power management circuit may reduce power consumption through clock gating and voltage control.

In one embodiment, the logic die 1200 may comprise an input/output interface 1210 configured to perform data input/output operations with an external device, and a filtering circuit 1220 configured to perform a filtering operation on data.

The input/output interface 1210 may comprise a high-speed physical layer (PHY) block, and may further comprise a data alignment circuit, a clock data recovery (CDR) circuit, a DLL/PLL circuit, a write leveling circuit, and a data training circuit. The input/output interface 1210 may align data DATA received from the external device according to an internal data bus format and transmit the data DATA to the global interconnection structure.

The filtering circuit 1220 may be configured to perform a filtering operation on the data DATA received through the input/output interface 1210 before the data DATA is stored in the first to K-th memory circuits 1110(1) to 1110(K) of the first to K-th core dies 1100(1) to 1100(K). For example, the filtering circuit 1220 may select only data satisfying a predetermined condition among the input data, remove unnecessary data, or transform a size of the data based on condition information stored in a condition register. The filtering circuit 1220 may generate filtered data F_DATA and transmit the filtered data F_DATA to a selected core die and memory bank through the TSVs.

In one embodiment, a detailed internal configuration of the filtering circuit 1220 may be the same as that described with reference to FIG. 2. Accordingly, the filtering circuit 1220 may comprise a filtering logic circuit (210 of FIG. 2), a first register (220 of FIG. 2), a filtered data queue (230 of FIG. 2), a counter (240 of FIG. 2), and a second register (250 of FIG. 2). The filtering logic circuit 210 may perform condition-based comparison, selection, masking, or arithmetic operations on the input data DATA. The first register 220 may store a filtering condition or operand OP and provide the filtering condition or operand OP to the filtering logic circuit 210. Filtered data F_DATA generated by the filtering logic circuit 210 may be temporarily stored in the filtered data queue 230. The filtering logic circuit 210 may further provide a signal SIG_CNT indicating occurrence of data satisfying the filtering condition to the counter 240. The counter 240 may count filtered data items and generate a count value VALUE_CNT. The count value may be stored in the second register 250 and provided to an external block or a higher-level control block.

FIGS. 3 to 7 illustrate various operational examples of the filtering circuit 1220. For example, the filtering circuit may select data within a specific range, combine multiple conditions for filtering, or perform filtering such that a size of input data and a size of filtered data are different or identical. The filtering operations described with reference to FIGS. 3 to 7 may be equally applied to the HBM structure of the present disclosure.

Although FIG. 15 illustrates a write operation, in one embodiment the filtering circuit 1220 may also receive data read from the first to K-th core dies 1100(1) to 1100(K), perform a filtering operation on the read data, and transmit filtered read data to the external device through the input/output interface 1210. In this case, the TSVs included in the first to K-th core dies 1100(1) to 1100(K) may also serve as high-bandwidth data transmission paths between the first to K-th core dies 1100(1) to 1100(K) and the logic die 1200.

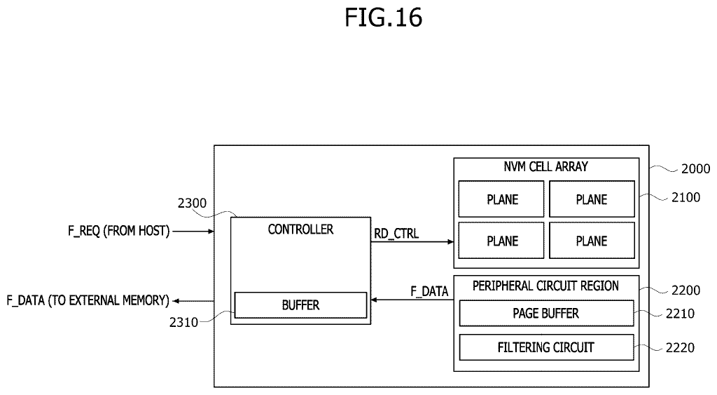

FIG. 16 illustrates a solid state drive (SSD) device including a filtering circuit according to an embodiment of the present disclosure.

Referring to FIG. 16, the SSD device 2000 may comprise a non-volatile memory (NVM) cell array 2100, a peripheral circuit region 2200 disposed adjacent to the non-volatile memory cell array 2100, and a controller 2300 configured to control the non-volatile memory cell array 2100.

The non-volatile memory cell array 2100 may comprise a plurality of planes. Each plane may comprise a plurality of memory blocks and pages, and may be configured to be independently accessible so as to support parallel operations. Such a plurality of planes may be configured to support parallel read and/or program operations in order to increase internal bandwidth.

The peripheral circuit region 2200 may be disposed adjacent to the non-volatile memory cell array 2100 and may comprise a page buffer 2210 and a filtering circuit 2220. The page buffer 2210 may be configured to sense and temporarily latch data read from the non-volatile memory cell array 2100. For example, the page buffer 2210 may be electrically connected to bit lines of the NVM cell array 2100 and may sense and latch data read from selected memory cells.

The filtering circuit 2220 may be configured to receive data read from the NVM cell array 2100 through the page buffer 2210. More specifically, the filtering circuit 2220 may be electrically connected to the page buffer 2210 so as to directly receive data latched in the page buffer 2210. The filtering circuit 2220 may perform a filtering operation on the data before the data is transmitted to the controller 2300, and may be configured to transmit filtered data F_DATA to the controller 2300.

Accordingly, the filtering circuit 2220 may reduce an amount of data transmitted from the non-volatile memory cell array 2100 to the controller 2300. In one embodiment, the controller 2300 may receive only the filtered data F_DATA resulting from the filtering operation performed by the filtering circuit 2220, such that unnecessary data transmission is reduced and internal data movement is decreased.

The controller 2300 may comprise a buffer 2310 configured to store the filtered data F_DATA. In one embodiment, when a size of the filtered data F_DATA stored in the buffer 2310 reaches a read unit of an external memory, for example a DRAM, the controller 2300 may be configured to provide the filtered data F_DATA to the external memory. In this manner, only the filtered data F_DATA may be provided to the external memory, and overall bandwidth utilization efficiency and energy efficiency of the system may be improved.

In one embodiment, the filtering circuit 2220 may perform the filtering operation such that a size of input data and a size of the filtered data F_DATA are different from each other. For example, the filtering circuit 2220 may reduce the data size by selecting only data satisfying a specific condition. In another embodiment, the filtering circuit 2220 may perform the filtering operation such that a size of input data and a size of the filtered data F_DATA are identical to each other. For example, masking or value transformation may be performed while maintaining an overall data length.

In one embodiment, the filtering circuit 2220 may comprise a filtering logic circuit configured to perform the filtering operation, a first register configured to provide a conditional operand to the filtering logic circuit, and a filtered data queue configured to temporarily store the filtered data. The filtering logic circuit may perform condition-based comparison, selection, or operations on the input data, and the first register may store a filtering condition and provide the filtering condition to the filtering logic circuit. The filtered data may be stored in the filtered data queue and then transmitted to the controller 2300. The filtering circuit 2220 may further comprise a counter configured to count a number of filtered data items and a second register configured to store a value counted by the counter. The count value may be provided to the controller 2300 or a higher-level control block for statistical processing or control determination.

In one embodiment, a plurality of filtering circuits 2220 may be provided and disposed to respectively correspond to the plurality of planes of the non-volatile memory cell array 2100. Such a structure enables plane-level parallel filtering operations. In addition, the filtering circuit 2220 may be configured to perform the filtering operation asynchronously in parallel with transmission of data to the controller 2300. For example, while the controller 2300 processes previously filtered data F_DATA, the filtering circuit 2220 may perform the filtering operation on subsequent data.

In FIG. 16, a filter request signal F_REQ may be input from a host, and the controller 2300 may generate a read control signal RD_CTRL in response thereto to control the non-volatile memory cell array 2100. Data read from the non-volatile memory cell array 2100 may pass through the page buffer 2210 and the filtering circuit 2220, be stored in the buffer 2310 of the controller 2300, and then be provided as filtered data F_DATA to an external device or an external memory. Although FIG. 16 illustrates a read filtering operation, the filtering circuit 2220 may be applied to other data paths depending on system requirements.

As described above, in the SSD device 2000 according to the present embodiment, data read from the non-volatile memory cell array 2100 is filtered by the filtering circuit 2220 disposed in the peripheral circuit region 2200 before being transmitted to the controller 2300. Accordingly, an amount of data transmitted to the controller 2300 may be reduced. The reduction in the amount of data transmitted to the controller 2300 may lead to reduced internal bus traffic, reduced buffer occupancy, and reduced memory access operations. Furthermore, unnecessary data movement may be reduced, thereby decreasing power consumption in internal interconnect structures. In addition, because a processing burden of the controller 2300 may be reduced, overall system response latency may be shortened and effective bandwidth may be improved under the same bandwidth environment. In particular, in big data analytics or data mining environments where only data satisfying specific conditions among large data sets is required, the present embodiment may achieve a significant reduction in data movement compared to conventional structures in which entire data sets are transmitted to the controller 2300 and an external device.

Meanwhile, the HBM structure illustrated in FIG. 15 and the SSD structure illustrated in FIG. 16 differ in terms of a placement location of the filtering circuit and a data path in which the filtering operation is performed. In the HBM device 1000 of FIG. 15, the filtering circuit 1220 is disposed in the logic die 1200 and is connected to the plurality of core dies 1100(1) to 1100(K) through the TSVs. That is, the filtering operation may be performed at a logic die level before data is stored in a memory cell array or before data read from the memory is transmitted externally. Such a structure enables logic-die-centric data preprocessing in a stacked DRAM-Based HBM architecture.

In contrast, in the SSD device 2000 of FIG. 16, the filtering circuit 2220 is disposed in the peripheral circuit region 2200 adjacent to the non-volatile memory cell array 2100. In this case, the filtering operation is performed before data latched in the page buffer 2210 is transmitted to the controller 2300. That is, in the SSD structure, filtering is performed along a data transfer path from a memory die to the controller within a peripheral region.

Accordingly, the HBM structure provides a processing-near-memory (PNM) architecture implemented at a logic die level in a stacked high-bandwidth memory environment, whereas the SSD structure provides preemptive data filtering within a peripheral circuit region of a non-volatile memory die. Although both structures perform filtering at an upstream stage along a data movement path, differences exist in a type of memory employed (DRAM-based HBM versus NAND-based SSD) and in a physical placement location of the filtering circuit.

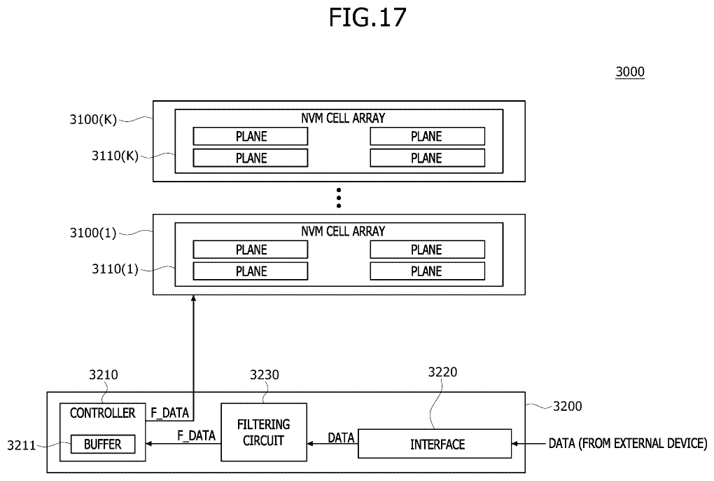

FIG. 17 illustrates a high bandwidth flash (HBF) device including a filtering circuit according to an embodiment of the present disclosure.

Referring to FIG. 17, the HBF device 3000 may comprise a plurality of NVM dies, for example, first to K-th NVM dies 3100(1)-3100(K), and a logic die 3200 stacked with the first to K-th NVM dies 3100(1)-3100(K), where K is a natural number equal to or greater than 2. The first to K-th NVM dies 3100(1)-3100(K) may respectively comprise first to K-th NVM cell arrays 3110(1)-3110(K). Each of the first to K-th NVM cell arrays 3110(1)-3110(K) may comprise a plurality of planes, and each plane may comprise a plurality of memory blocks and pages. The plurality of planes may be configured to support parallel read and/or program operations, thereby improving internal bandwidth.

In an embodiment, each of the first to K-th NVM dies 3100(1)-3100(K) may be implemented in a CMOS Directly Bonded to Array (CBA) structure. The CBA structure refers to a structure in which a wafer including a memory cell array and a wafer including CMOS circuitry are separately fabricated and then directly bonded to each other. According to such a structure, a high-temperature process for forming the NVM cell array and a process for forming CMOS logic may be separately optimized. For example, a three-dimensional NAND memory cell array may require manufacturing processes including high-temperature thermal treatment, whereas highly integrated control logic may advantageously be formed using an advanced CMOS process node. The CBA structure separates such process characteristics, thereby allowing each wafer to be fabricated under independently optimized conditions.

Furthermore, the CBA structure may enable implementation of high-performance control logic using advanced process nodes. For example, complex control logic included in the filtering circuit 3230 or the controller 3210, an error correction code (ECC) block, wear-leveling logic, and high-speed interface circuitry may be implemented in a CMOS wafer fabricated using a fine process node. In contrast, the NVM cell array may be optimized for achieving high storage density.

Accordingly, the CBA structure may provide effects such as improved manufacturing flexibility through process separation, increased capability for implementing highly integrated logic, and improved integration with high-bandwidth interfaces. Furthermore, in the HBF structure according to the present embodiment, a plurality of NVM dies implemented in the CBA structure may be stacked and electrically connected to the logic die 3200. In this case, CMOS circuitry and the memory cell array within each NVM die may be separately fabricated and directly bonded, and the NVM dies and the logic die may be connected through TSVs or hybrid bonding structures. As a result, both highly integrated control logic and high-capacity memory arrays may be simultaneously implemented in a multi-layer stacked structure.

In an embodiment, the first to K-th NVM dies 3100(1)-3100(K) may be implemented as three-dimensional stacked NAND flash memory. The first to K-th NVM dies 3100(1)-3100(K) may have a stacked structure. Each of the first to K-th NVM dies 3100(1)-3100(K) may include TSVs. A bonding structure between the NVM dies may be implemented in various ways. For example, the first to K-th NVM dies 3100(1)-3100(K) may be electrically connected to one another through hybrid bonding, micro-bumps, Cu-Cu direct bonding, or the like.

The first to K-th NVM dies 3100(1)-3100(K) may be electrically connected to the logic die 3200. The logic die 3200 may include vertical interconnects such as TSVs. In one embodiment, a connection between the TSVs of the first to K-th NVM dies 3100 and the TSVs of the logic die 3200 may be achieved through a hybrid bonding structure. The hybrid bonding structure may provide lower resistance and higher interconnection density than a TSV-based connection and may be advantageous for high-bandwidth data transmission. In another embodiment, the TSVs of the first NVM die 3100 and the TSVs of the logic die 3200 may be electrically connected to each other through a bump structure.

The logic die 3200 may be configured as a separate die from the first to K-th NVM dies 3100(1)-3100(K) and may be disposed at a lower or upper portion of the stacked structure. In an embodiment, the logic die 3200 may comprise a controller 3210, an interface 3220, and a filtering circuit 3230.

The controller 3210 may be configured to control the first to K-th NVM dies 3100(1)-3100(K). For example, the controller 3210 may comprise flash control logic, an address decoder, wear-leveling logic, and an error correction code (ECC) block. The controller 3210 may further comprise an internal buffer 3211 configured to store filtered data F_DATA. When a size of the filtered data F_DATA stored in the internal buffer 3211 reaches a request unit of an external device, the controller 3210 may be configured to provide the filtered data F_DATA to the external device through the interface 3220.

The interface 3220 may be configured to perform data input/output operations with an external device. In an embodiment, the interface 3220 may comprise a data alignment circuit, a protocol processing circuit, and a high-speed PHY block.

The filtering circuit 3230 may be configured to perform a filtering operation on data. The filtering circuit 3230 may receive data read from the first to K-th NVM dies 3100(1)-3100(K), perform a filtering operation on the received data before the data is processed by the controller 3210, and transmit filtered data F_DATA to the controller 3210.

In an embodiment, a plurality of filtering circuits 3230 may be provided and may be disposed to respectively correspond to the first to K-th NVM dies 3100(1)-3100(K). In another embodiment, the filtering circuit 3230 may be disposed in a central region of the logic die 3200 and may be commonly connected to the first to K-th NVM dies 3100(1)-3100(K).

In an embodiment, as described with reference to FIG. 2, the filtering circuit 3230 may comprise a filtering logic circuit configured to perform the filtering operation, a first register configured to provide a conditional operand to the filtering logic circuit, and a filtered data queue configured to temporarily store filtered data F_DATA. The filtering circuit 3230 may further comprise a counter configured to count a number of filtered data items F_DATA and a second register configured to store a value counted by the counter.

In an embodiment, the filtering circuit 3230 may perform the filtering operation such that a size of input data and a size of filtered data F_DATA are different from each other. In another embodiment, the filtering circuit 3230 may perform the filtering operation such that a size of input data and a size of filtered data F_DATA are identical to each other. In an embodiment, the filtering circuit 3230 may be configured to transmit only data satisfying a condition among entire data to the controller 3210, such that an amount of data transmitted to the controller 3210 may be smaller than an amount of data received from the first to K-th NVM dies 3100(1)-3100(K). The filtering circuit 3230 may be configured to perform the filtering operation asynchronously in parallel with reception of data from the first to K-th NVM dies 3100(1)-3100(K).

Data DATA input from an external device to the logic die 3200 may be transmitted to the filtering circuit 3230 through the interface 3220. The filtering circuit 3230 may perform a filtering operation on the received data DATA and may cause the controller 3210 to write the filtered data into a selected memory die and plane.

Data read from the first to K-th NVM dies 3100(1)-3100(K) may be transmitted to the controller 3210 of the logic die 3200. The controller 3210 may transmit the received data to the filtering circuit 3230. The filtering circuit 3230 may perform a filtering operation on the received data and may transmit filtered data to an external device through the interface 3220.

The HBF device 3000 according to the present embodiment may simultaneously provide a stacked NAND-based memory die structure, a flash controller integrated within the logic die, a filtering operation performed before processing by the controller, and high-bandwidth connections based on TSVs or hybrid bonding. Accordingly, compared to a conventional SSD structure, the HBF device may achieve reduced data movement and reduced latency. Furthermore, the HBF device may have structural differentiation in that a stacked structure similar to HBM is maintained while combining characteristics of NAND-based non-volatile memory.

Concepts have been disclosed in conjunction with some embodiments as described above. Those skilled in the art will appreciate that various modifications, additions, and substitutions are possible, without departing from the scope and spirit of the present disclosure. Accordingly, the embodiments disclosed in the present specification should be considered from not a restrictive standpoint but rather from an illustrative standpoint. The scope of the concepts is not limited to the above descriptions but defined by the accompanying claims, and all of distinctive features in the equivalent scope should be construed as being included in the concepts.

What is claimed is:

1. A high bandwidth memory (HBM) device comprising:
a plurality of core dies each including a plurality of memory circuits; and
a logic die stacked with the plurality of core dies,
wherein the logic die comprises:
a filtering circuit configured to perform a filtering operation on data; and
an input/output interface configured to perform a data input/output operation with an external device,
wherein the filtering circuit is configured to:
directly receive write data from the external device through the input/output interface,
perform the filtering operation on the write data before the write data is stored in the plurality of memory circuits, and
transmit filtered write data to at least one of the plurality of memory circuits.

2. The HBM device of claim 1,
wherein each of the plurality of memory circuits comprises a memory bank, and
wherein the logic die and the plurality of core dies are electrically connected to each other by through-silicon vias (TSVs).

3. The HBM device of claim 1, further comprising:
a global interconnection structure providing data transmission paths among the plurality of core dies, the logic die, and the input/output interface,
wherein the filtered write data is transmitted to at least one of the plurality of memory circuits through the global interconnection structure.

4. The HBM device of claim 1,
wherein the filtering circuit is configured to:
receive read data from the plurality of memory circuits,
perform the filtering operation on the read data, and
output filtered read data to the external device through the global interconnection structure and the input/output interface.

5. The HBM device of claim 1,
wherein the filtering circuit is configured to perform the filtering operation such that a size of input data and a size of filtered data are different from each other.

6. The HBM device of claim 1,
wherein the filtering circuit is configured to perform the filtering operation such that a size of input data and a size of filtered data are identical to each other.

7. The HBM device of claim 1,
wherein the filtering circuit comprises:
a filtering logic circuit configured to perform the filtering operation;
a first register configured to provide a conditional operand to the filtering logic circuit; and
a filtered data queue configured to store filtered data.

8. The HBM device of claim 7,
wherein the filtering circuit further comprises:
a counter configured to count a number of filtered data items; and
a second register configured to store a value counted by the counter.

9. The HBM device of claim 1,
wherein a plurality of filtering circuits are disposed in the logic die to respectively correspond to the plurality of core dies.

10. The HBM device of claim 1,
wherein the filtering circuit is disposed in a central region of the logic die and is commonly connected to the plurality of core dies.

11. The HBM device of claim 1,
wherein the filtering circuit is configured to store only data satisfying a predetermined condition among entire data loaded from the external device into the plurality of memory circuits.

12. The HBM device of claim 1,
wherein an amount of data transmitted to the plurality of memory circuits by the filtering circuit is smaller than an amount of data received from the external device.

13. A solid state drive (SSD) device comprising:
a non-volatile memory cell array comprising a plurality of planes;
a peripheral circuit region disposed adjacent to the non-volatile memory cell array, the peripheral circuit region comprising a page buffer and a filtering circuit; and
a controller configured to control the non-volatile memory cell array,
wherein the filtering circuit is configured to:
receive data read from the non-volatile memory cell array through the page buffer,
perform a filtering operation on the data before the data is transmitted to the controller, and
transmit filtered data to the controller.

14. The SSD device of claim 13,
wherein the filtering circuit is electrically connected to the page buffer to directly receive data latched in the page buffer.

15. The SSD device of claim 13,
wherein the controller is configured such that an amount of data transmitted to the controller is reduced by the filtering operation.

16. The SSD device of claim 13,
wherein the controller comprises a buffer configured to store filtered data,
and wherein the controller is configured to provide the filtered data to an external device when a size of the filtered data stored in the buffer reaches a read unit size of the external device.

17. The SSD device of claim 13,
wherein the filtering circuit is configured to perform the filtering operation such that a size of input data and a size of filtered data are different from each other.

18. The SSD device of claim 13,
wherein the filtering circuit is configured to perform the filtering operation such that a size of input data and a size of filtered data are identical to each other.

19. The SSD device of claim 13,
wherein the filtering circuit comprises:
a filtering logic circuit configured to perform the filtering operation;
a first register configured to provide a conditional operand to the filtering logic circuit; and
a filtered data queue configured to temporarily store filtered data.

20. The SSD device of claim 19,
wherein the filtering circuit further comprises:
a counter configured to count a number of filtered data items; and
a second register configured to store a value counted by the counter.

21. The SSD device of claim 13,
wherein a plurality of filtering circuits are disposed to respectively correspond to the plurality of planes.

22. The SSD device of claim 13,
wherein the filtering circuit is configured to perform the filtering operation asynchronously in parallel with transmission of data to the controller.

23. A high bandwidth flash (HBF) device comprising:
a plurality of memory dies each comprising a non-volatile memory cell array; and
a logic die stacked with the plurality of memory dies,
wherein the logic die comprises:
a controller configured to control the plurality of memory dies;
a filtering circuit configured to perform a filtering operation on data; and
an interface configured to perform a data input/output operation with an external device,
wherein the filtering circuit is configured to:
receive data read from the plurality of memory dies,
perform the filtering operation on the data before the data is processed by the controller, and
transmit filtered data to the controller.

24. The HBF device of claim 23,
wherein the plurality of memory dies are electrically connected to the logic die by through-silicon vias (TSVs) or hybrid bonding.

25. The HBF device of claim 23,
wherein the logic die further comprises a global interconnection structure configured to transmit data received from the plurality of memory dies.

26. The HBF device of claim 23,
wherein a plurality of filtering circuits are disposed to respectively correspond to the plurality of memory dies.

27. The HBF device of claim 23,
wherein the filtering circuit is disposed in a central region of the logic die and is commonly connected to the plurality of memory dies.

28. The HBF device of claim 23,
wherein the filtering circuit is configured to perform the filtering operation such that a size of input data and a size of filtered data are different from each other.

29. The HBF device of claim 23,
wherein the filtering circuit is configured to perform the filtering operation such that a size of input data and a size of filtered data are identical to each other.

30. The HBF device of claim 23,
wherein the filtering circuit comprises:
a filtering logic circuit configured to perform the filtering operation;
a first register configured to provide a conditional operand to the filtering logic circuit; and
a filtered data queue configured to temporarily store filtered data.

31. The HBF device of claim 30,
wherein the filtering circuit further comprises:
a counter configured to count a number of filtered data items; and
a second register configured to store a value counted by the counter.

32. The HBF device of claim 23,
wherein the filtering circuit is configured to transmit only data satisfying a predetermined condition among entire data read from the plurality of memory dies to the controller.

33. The HBF device of claim 23,
wherein an amount of data transmitted to the controller by the filtering circuit is smaller than an amount of data received from the plurality of memory dies.

34. The HBF device of claim 23,
wherein the controller comprises an internal buffer configured to store filtered data,
and wherein the controller is configured to provide the filtered data to the external device through the interface when a size of the filtered data stored in the internal buffer reaches a request unit size of the external device.

35. The HBF device of claim 23,
wherein the filtering circuit is configured to perform the filtering operation asynchronously in parallel with reception of data from the plurality of memory dies.
